(19) United States
(12) Patent Application Publication
(10) Pub. No.: US 2005/0145851 A1
(43) Pub. Date: Jul. 7, 2005

(54) Gallium nitride material structures including isolation regions and methods

(75) Inventors: Jerry W. Johnson, Raleigh, NC (US); Ricardo Borges, Morrisville, NC (US); Jeffrey D. Brown, Garner, NC (US); James W. Cook JR., Raleigh, NC (US); Allen W. Hanson, Cary, NC (US); Edwin L. Piner, Cary, NC (US); Pradeep Rajagopal, Raleigh, NC (US); John C. Roberts, Hillsborough, NC (US); Sameer Singhal, Apex, NC (US); Robert J. Therrien, Apex, NC (US); Andrei Vescan, Herzogenrath (DE)

Correspondence Address: WOLF GREENFIELD & SACKS, PC;FEDERAL RESERVE PLAZA, 600 ATLANTIC AVENUE, BOSTON, MA, 02210-2211, US

(73) Assignee: Nitronex Corporation, Raleigh, NC (US)

(21) Appl. No.: 10/879,695

(22) Filed: Jun. 28, 2004

Related U.S. Application Data
(63) Continuation-in-part of application No. 10/740,376, filed on Dec. 17, 2003.

(51) Int. Cl. H01L 29/15

(52) U.S. Cl. 257/76

(57) ABSTRACT

Gallium nitride material structures, including devices, and methods associated with the same are provided. In some embodiments, the structures include one or more isolation regions which electrically isolate adjacent devices. One aspect of the invention is the discovery that the isolation regions also can significantly reduce the leakage current of devices (e.g., transistors) made from the structures, particularly devices that also include a passivating layer formed on a surface of the gallium nitride material. Lower leakage currents can result in increased power densities and operating voltages, amongst other advantages.

### RELATED APPLICATIONS

This application is a continuation-in-part of U.S. patent application Ser. No. 10/740,376, filed Dec. 17, 2003, and entitled “Gallium Nitride Material Devices Including An Electrode-Defining Layer and Methods of Forming the Same”, the disclosure of which is incorporated herein by reference.

### FIELD OF INVENTION

The invention relates generally to gallium nitride materials and, more particularly, to gallium nitride material structures that include isolation regions and methods associated with the same.

### BACKGROUND OF INVENTION

Gallium nitride materials include gallium nitride (GaN) and its alloys such as aluminum gallium nitride (AlGaN), indium gallium nitride (InGaN), and aluminum indium gallium nitride (AlInGaN). These materials are semiconductor compounds that have a relatively wide, direct bandgap which permits highly energetic electronic transitions to occur. Gallium nitride materials have a number of attractive properties including high electron mobility, the ability to efficiently emit blue light, the ability to transmit signals at high frequency, and others. Accordingly, gallium nitride materials are being widely investigated in many microelectronic applications such as transistors and optoelectronic devices.

Despite the attractive properties noted above, a number of challenges exist when developing gallium nitride material-based devices. For example, leakage current can sacrifice performance in gallium nitride material-based devices (e.g., transistors). In particular, leakage current can limit the operating voltage and/or power density of the device (e.g., transistors). Thus, devices that exhibit high leakage currents typically have inferior, and oftentimes unacceptable, performance characteristics.

### SUMMARY OF INVENTION

The invention provides gallium nitride material structures (including devices) and methods associated with the same.

In one embodiment, a semiconductor device is provided. The device comprises a silicon substrate; a gallium nitride material region formed on the silicon substrate and having an active region formed therein; a passivating layer formed on the gallium nitride material region; and an isolation region formed in the gallium nitride material region and electrically isolating, at least in part, the active region.

In another embodiment, a method is provided. The method comprises forming an isolation region in a gallium nitride material region of a device; and forming a passivating layer on a gallium nitride material region of a device without increasing the isolation current of the isolation region by a factor of greater than about 100 times.

In another embodiment, a method is provided. The method comprises forming an isolation region in a gallium nitride material region of a device; and forming a passivating layer on a gallium nitride material region of a device without increasing the isolation current of the isolation region by a factor of greater than about 100 times.

In another embodiment, a method is provided. The method comprises forming an isolation region in a gallium nitride material region of a FET; and forming a passivating layer on a gallium nitride material region of the FET without increasing leakage current of the FET by greater than about 100% at a drain bias of 28 V.

In another embodiment, a FET is provided. The FET comprises a silicon substrate, and a gallium nitride material region formed over the silicon substrate. The FET is capable of operating at a power density of at least 7 W/mm when biased at 28 Volts.

In another embodiment, a FET is provided. The FET comprises a silicon substrate; a gallium nitride material region formed over the silicon substrate; an implanted region formed in the gallium nitride material region; wherein the FET is capable of operating at a power density of at least 5 W/mm when biased at greater than or equal to 28 Volts.

In another embodiment, a FET is provided. The FET comprises a silicon substrate; and a gallium nitride material region formed on the silicon substrate, wherein the breakdown voltage of the FET is greater than or equal to 40 V per micron of gate-to-drain separation.

Other aspects, embodiments and features of the invention will become apparent from the following detailed description of the invention when considered in conjunction with the accompanying drawings. The accompanying figures are schematic and are not intended to be drawn to scale. In the figures, each identical, or substantially similar component that is illustrated in various figures is represented by a single numeral or notation. For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF DRAWINGS

FIG. 1A is a cross-section of a gallium nitride material device including an implanted isolation region according to an embodiment of the invention.

FIG. 1B is a top view of the device of FIG. 1A taken along line 1B-1B.

FIG. 2 is a cross-section of a gallium nitride material device including an implanted isolation region according to an embodiment of the invention.

FIG. 3 is a sheet resistance (Rₛₕ) uniformity map as described in Example 1.

FIG. 4 shows typical output characteristics of the HFET structures described in Example 1.

FIG. 5 shows a continuous-wave 2.14 GHz power sweep of an HFET structure as described in Example 1.

FIG. 6 are respective cross-sections of mesa-etched and implanted isolation test structures with and without a passivating layer as described in Example 2.

FIG. 7 is a plot of isolation current for passivated isolation test structures vs. isolation current of unpassivated isolation test structures as described in Example 2.

### DETAILED DESCRIPTION

The invention provides gallium nitride material structures (including devices) and methods associated with the same. In some embodiments, the structures include one or more region(s) which electrically isolate one portion of the structure from another portion. For example, the region(s) may electrically isolate an active device region from adjacent conducting structures (e.g., electrodes, contacts, active region of adjacent devices). The isolation regions may be formed, for example, using an implantation process. One aspect of the invention is the discovery that the isolation regions(s) also can significantly reduce the leakage current of devices (e.g., transistors) made from the structures, particularly devices that also include a passivating layer formed on a surface of the gallium nitride material. Lower leakage currents can result in increased power densities and operating voltages, amongst other advantages.

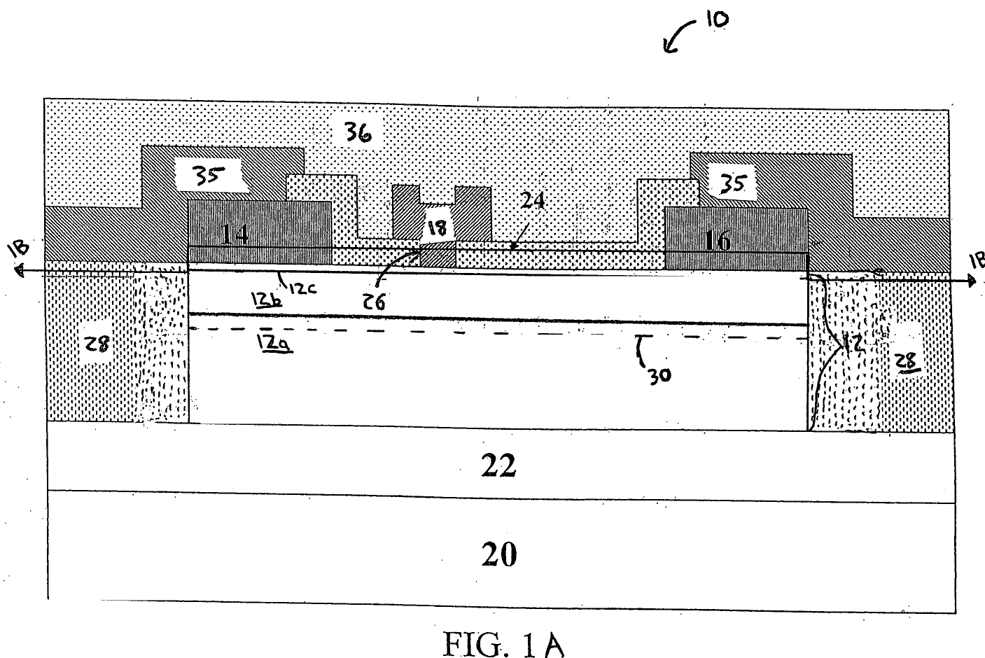

FIGS. 1A and 1B illustrate a semiconductor device 10 that includes a gallium nitride material region 12 according to one embodiment of the invention. In the illustrative embodiment, device 10 is a field effect transistor (FET) that includes a source electrode 14, a drain electrode 16 and a gate electrode 18 formed on the gallium nitride material region. The gallium nitride material region is formed on a substrate 20 and, as shown, a transition layer 22 may be formed between the substrate and the gallium nitride material region. The device includes a passivating layer 24 that protects and passivates the surface of the gallium nitride material region. In the illustrative embodiment, a via 26 is formed within the passivating layer in which the gate electrode is, in part, formed. Isolation region 28 electrically isolates an active region 30 of the device by limiting unwanted current flow (e.g., from the source) outside the active region to conducting structures on the device (e.g., gate and drain electrodes; contact pads of the source, drain and gate electrodes; and, active regions of adjacent device(s) formed on the same substrate.). As described further below, the isolation region contributes to reducing the leakage current of the device, as well as increasing the power density and operating voltage, amongst other advantages.

Though in the illustrative embodiment of FIGS. 1A and 1B device 10 is a FET, the invention encompasses other types of devices including, for example, Schottky diodes and solid-state switching devices.

When a layer is referred to as being “on” or “over” another layer or substrate, it can be directly on the layer or substrate, or an intervening layer also may be present. A layer that is “directly on” another layer or substrate means that no intervening layer is present. It should also be understood that when a layer is referred to as being “on” or “over” another layer or substrate, it may cover the entire layer or substrate, or a portion of the layer or substrate.

Isolation region 28 is sufficiently insulating to effectively electrically isolate the active region. It should be understood that when the term “isolation” is used in connection with region 28, the term generally refers to electrically isolation. The isolation region, for example, may have a sheet resistance of greater than about 10⁹ Ohms/sq., such as between about 10⁹ Ohms/sq. and about 10¹² Ohms/sq. The isolation region may be rendered sufficiently insulating by the generation of defects (e.g., vacancies), for example, during the implantation process. The presence of a high vacancy concentration limits, or prevents, the transport of free carriers (e.g., electrons or holes) which contribute to the conductivity of the material. The high vacancy concentration also can result in the material having an amorphous (i.e., non-crystalline) structure. The vacancy concentration, in some embodiments, is greater than about 10¹⁸ vacancies/cm³ and, in some embodiments, is greater than about 10²⁰ vacancies/cm³.

As described further below, a number of different types of species may be implanted to form the isolation region. The species include, but are not limited, to nitrogen ions, argon ions, helium ions and oxygen ions amongst others. The implanted species are typically incorporated into the structure of the isolation region.

In some embodiments, it is preferred that the isolation region completely surrounds active region 30. That is, the isolation region extends around the perimeter of the active region, but not typically beneath the active region. In the illustrative embodiment, the isolation region is formed in all areas within the gallium nitride material region other than the active region. However, in other embodiments, the isolation region may not be formed in all areas within the gallium nitride material region other than the active region. For example, the isolation region may not extend within the gallium nitride material region up to the edge of the source electrode and/or the drain electrode.

As used herein, the active region is defined as the area in the gallium nitride material region in which free carriers flow (i.e., electrons or holes) in desired direction(s) during device operation. In FET embodiments, the active region is defined as the area in the gallium nitride material region in which free carriers flow from the source electrode to the drain electrode. In the illustrative embodiment, the active region is formed within a portion of the gallium nitride material region between the source electrode and the drain electrode. The active region may also extend beneath the source electrode and the drain electrode, as shown. In other embodiments, the active area may extend only beneath a portion of the source electrode and/or the drain electrode (e.g., when the isolation region extends beneath other portions of the source electrode and/or drain electrode).

It should be understood that, in other embodiments, the isolation region may isolate another portion (or portions) of the device. Also, the isolation region may have a different relationship with respect to the active region. For example, in some embodiments, the isolation region may not completely surround the active region. However, in these embodiments, all of the advantages associated with the isolation region completely surrounding the active region may not be achieved. Also, in non-FET embodiments, the isolation region may be positioned differently.

Isolation region 28 extends to a depth sufficient to effectively isolate the active region. As shown, the isolation region extends entirely through the gallium nitride material region. In other embodiments, the isolation region extends into transition layer 22. In some cases, the isolation region may even extend into the substrate, though oftentimes it is not necessary for the isolation region to extend to such a depth within the structure to provide sufficient isolation.

The isolation region may also only extend through a portion of the gallium nitride material region. As described further below, in the illustrative embodiment, gallium nitride material region includes a first gallium nitride material layer 12b formed on a second gallium nitride material layer 12a. When layer 12b has a higher aluminum concentration than layer 12a (e.g., layer 12b is formed of AlₓGa₍₁₋ₓ₎N and layer 12a is formed of GaN), a highly conductive region (i.e., a 2-DEG region) may be formed at the surface of layer 12a, as known to those of ordinary skill in the art. In these embodiments, it is generally preferable for the isolation region to extend at least through the 2-DEG region to provide effective isolation. The 2-DEG region, for example, may extend about 15 nm from the interface between layer 12b and layer 12a.

As noted above, the device includes passivating layer 24 formed on the surface of gallium nitride material region 12. Suitable passivating layers (some of which also function as electrode-defining layers) have been described in U.S. patent application Ser. No. 10/740,376, incorporated by reference above. As used herein, the term “passivating layer” refers to any layer that when formed on an underlying layer (e.g., gallium nitride material region 12) reduces the number and/or prevents formation of surface/interface states in the bandgap of the underlying layer, or reduces the number and/or prevents formation of free carrier (e.g., electron or hole) trapping states at the surface/interface of the underlying layer. The trapping states, for example, may be associated with surface states created by unterminated chemical bonds, threading dislocations at the surface or ions adsorbed to the surface from the environment. In a FET device, the trapping states may capture free carriers or may create undesired depletion regions during DC or RF operation. These effects may cause a decrease in the amount of current that otherwise would flow in a channel of the FET during operation, thus, impairing the performance of the device. The passivating layer may substantially reduce these effects thereby improving electrical performance of the device such as increased power density and/or efficiency. The passivating layer may also increase the breakdown voltage of the device.

It should be understood that a passivating layer may also protect the underlying layer (e.g. gallium nitride material region 12) during subsequent processing steps including photolithography, etching, metal (e.g., gate, interconnect) deposition, implantation, wet chemical, and resist strip (e.g., in a plasma) steps. Thus, a passivating layer may limit or eliminate reactions and/or interactions of other processing species (e.g., liquids, ions, plasmas, gaseous species) with the surface of the gallium nitride material. These reactions and/or interactions can be detrimental to the electrical properties of the device by changing surface morphology, the number of surface states, the amount of surface charge, the polarity of surface charge, or any combination of these.

Suitable compositions for passivating layer 24 include, but are not limited to, nitride-based compounds (e.g., silicon nitride compounds), oxide-based compounds (e.g., silicon oxide compounds), polyimides, other dielectric materials, or combinations of these compositions (e.g., silicon oxide and silicon nitride). In some cases, it may be preferable for the passivating layer to be a silicon nitride compound (e.g., Si₃N₄) or non-stoichiometric silicon nitride compounds.

The thickness of passivating layer 24 depends on the design of the device. In some cases, the passivating layer may have a thickness of between about 50 Angstroms and 1.0 micron. In some cases, the thickness may be between about 700 Angstroms and about 1200 Angstroms.

As shown, the passivating layer covers the entire surface of gallium nitride material region 12 with the exception of the electrode regions (source 14, drain 16 and gate 18).

Though the passivating layer in FIGS. 1A and 1B functions as an electrode-defining layer, in other embodiments the passivating layer may not function as an electrode-defining layer.

It has been discovered that the passivating layer may contribute to increasing the leakage current of devices including gallium nitride material regions. As described further below, the leakage current of such devices may be reduced by formation of isolation regions according to methods of the present invention.

In certain preferred embodiments, substrate 20 is a silicon substrate. As used herein, a silicon substrate refers to any substrate that includes a silicon surface. Examples of suitable silicon substrates include substrates that are composed entirely of silicon (e.g., bulk silicon wafers), silicon-on-insulator (SOI) substrates, silicon-on-sapphire substrate (SOS), and SIMOX substrates, amongst others. Suitable silicon substrates also include substrates that have a silicon wafer bonded to another material such as diamond, AlN, or other polycrystalline materials. Silicon substrates having different crystallographic orientations may be used. In some cases, silicon (111) substrates are preferred. In other cases, silicon (100) substrates are preferred.

It should be understood that other types of substrates may also be used including sapphire, silicon carbide, indium phosphide, silicon germanium, gallium arsenide, gallium nitride material, aluminum nitride, or other III-V compound substrates. However, in embodiments that do not use silicon substrates, all of the advantages associated with silicon substrates may not be achieved.

It should also be understood that though the illustrative embodiments include a substrate, other embodiments of the invention may not have a substrate. In these embodiments, the substrate may be removed during processing. In other embodiments, the substrate may also function as the gallium nitride material region. That is, the substrate and gallium nitride material region are the same region.

Substrate 20 may have any suitable dimensions and its particular dimensions are dictated, in part, by the application and the substrate type. Suitable diameters may include, but are not limited to, 2 inches (50 mm), 4 inches (100 mm), 6 inches (150 mm), and 8 inches (200 mm).

In some cases, it may be preferable for the substrate to be relatively thick, such as greater than about 125 micron (e.g., between about 125 micron and about 800 micron, or between about 400 micron and 800 micron). Relatively thick substrates may be easy to obtain, process, and can resist bending which can occur, in some cases, when using thinner substrates. In other embodiments, thinner substrates (e.g., less than 125 microns) are used. Though thinner substrates may not have the advantages associated with thicker substrates, thinner substrates can have other advantages including facilitating processing and/or reducing the number of processing steps. In some processes, the substrate initially is relatively thick (e.g., between about 200 microns and 800 microns) and then is thinned during a later processing step (e.g., to less than 150 microns).

In some preferred embodiments, the substrate is substantially planar in the final device or structure. Substantially planar substrates may be distinguished from substrates that are textured and/or have trenches formed therein (e.g., as in U.S. Pat. No. 6,265,289). In the illustrative embodiments, the regions/layers formed on the substrate (e.g., transition layer, gallium nitride material region, and the like) may also be substantially planar. As described further below, such regions/layers may be grown in vertical (e.g., non-lateral) growth processes. Planar substrates and regions/layers can be advantageous in some embodiments, for example, to simplify processing. Though it should be understood that, in some embodiments of the invention, lateral growth processes may be used as described further below.

Transition layer 22 may be formed on substrate 20 prior to the deposition of gallium nitride material region 12. The transition layer may accomplish one or more of the following: reducing crack formation in the gallium nitride material region 12 by lowering thermal stresses arising from differences between the thermal expansion rates of gallium nitride materials and the substrate; reducing defect formation in gallium nitride material region by lowering lattice stresses arising from differences between the lattice constants of gallium nitride materials and the substrate; and, increasing conduction between the substrate and gallium nitride material region by reducing differences between the band gaps of substrate and gallium nitride materials. The presence of the transition layer may be particularly preferred when utilizing silicon substrates because of the large differences in thermal expansion rates and lattice constant between gallium nitride materials and silicon. It should be understood that the transition layer also may be formed between the substrate and gallium nitride material region for a variety of other reasons. In some cases, for example when a silicon substrate is not used, the device may not include a transition layer.

The composition of transition layer 22 depends, at least in part, on the type of substrate and the composition of gallium nitride material region 12. In some embodiments which utilize a silicon substrate, the transition layer may preferably comprise a compositionally-graded transition layer having a composition that is varied across at least a portion of the layer. Suitable compositionally-graded transition layers, for example, have been described in commonly-owned U.S. Pat. No. 6,649,287, entitled “Gallium Nitride Materials and Methods,” filed on Dec. 14, 2000, which is incorporated herein by reference. Compositionally-graded transition layers are particularly effective in reducing crack formation in the gallium nitride material region by lowering thermal stresses that result from differences in thermal expansion rates between the gallium nitride material and the substrate (e.g., silicon). In some embodiments, when the compositionally-graded, transition layer is formed of an alloy of gallium nitride such as AlₓIn_{y}Ga_{(1-x-y)}N, AlₓGa₍₁₋ₓ₎N, or In_{y}Ga_{(1-y)}N, wherein 0≦x≦1, 0≦y≦1. In these embodiments, the concentration of at least one of the elements (e.g., Ga, Al, In) of the alloy is typically varied across at least a portion of the cross-sectional thickness of the layer. For example; when the transition layer has an AlₓIn_{y}Ga_{(1-x-y)}N composition, x and/or y may be varied; when the transition layer has a AlₓGa₍₁₋ₓ₎N composition, x may be varied; and, when the transition layer has a In_{y}Ga_{(1-y)}N composition, y may be varied.

In certain preferred embodiments, it is desirable for the transition layer to have a low gallium concentration at a back surface which is graded to a high gallium concentration at a front surface. It has been found that such transition layers are particularly effective in relieving internal stresses within the gallium nitride material region. For example, the transition layer may have a composition of AlₓGa₍₁₋ₓ₎N, where x is decreased from the back surface to the front surface of the transition layer (e.g., x is decreased from a value of 1 at the back surface of the transition layer to a value of 0 at the front surface of the transition layer). The composition of the transition layer, for example, may be graded discontinuously (e.g., step-wise) or continuously. One discontinuous grade may include steps of AlN, Al_{0.6}Ga_{0.4}N and Al_{0.3}Ga_{0.7}N proceeding in a direction toward the gallium nitride material region.

In some cases, the transition layer has a monocrystalline structure.

It should be understood that, in some embodiments, transition layer 22 has a constant (i.e., non-varying) composition across its thickness.

Gallium nitride material region 12 comprises at least one gallium nitride material layer. As used herein, the phrase “gallium nitride material” refers to gallium nitride (GaN) and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosporide nitride (GaAsₐP_{b}N_{(1-a-b)}), aluminum indium gallium arsenide phosporide nitride (AlₓIn_{y}Ga_{(1-x-y)}AsₐP_{b}N_{(1-a-b)}), amongst others. Typically, when present, arsenic and/or phosphorous are at low concentrations (i.e., less than 5 weight percent). In certain preferred embodiments, the gallium nitride material has a high concentration of gallium and includes little or no amounts of aluminum and/or indium. In high gallium concentration embodiments, the sum of (x+y) may be less than 0.4, less than 0.2, less than 0.1, or even less. In some cases, it is preferable for the gallium nitride material layer to have a composition of GaN (i.e., x+y=0). Gallium nitride materials may be doped n-type or p-type, or may be intrinsic. Suitable gallium nitride materials have been described in U.S. Pat. No. 6,649,287, incorporated by reference above.

In some cases, the gallium nitride material region includes only one gallium nitride material layer. In other cases, the gallium nitride material region includes more than one gallium nitride material layer. For example, the gallium nitride material region may include multiple layers (12a, 12b, 12c), as shown. In certain embodiments, it may be preferable for the gallium nitride material of layer 12b to have an aluminum concentration that is greater than the aluminum concentration of the gallium nitride material of layer 12a. For example, the value of x in the gallium nitride material of layer 12b (with reference to any of the gallium nitride materials described above) may have a value that is between 0.05 and 1.0 greater than the value of x in the gallium nitride material of layer 12a, or between 0.05 and 0.5 greater than the value of x in the gallium nitride material of layer 12a. For example, layer 12b may be formed of Al_{0.26}Ga_{0.74}N, while layer 12a is formed of GaN. This difference in aluminum concentration may lead to formation of a highly conductive region at the interface of the layers 12a, 12b (i.e., a 2-D electron gas region). In the illustrative embodiment, layer 12c may be formed of GaN.

Gallium nitride material region 12 also may include one or more layers that do not have a gallium nitride material composition such as other III-V compounds or alloys, oxide layers, and metallic layers.

The gallium nitride material region is of high enough quality so as to permit the formation of devices therein. Preferably, the gallium nitride material region has a low crack level and a low defect level. As described above, transition layer 22 (particularly when compositionally-graded) may reduce crack and/or defect formation. Gallium nitride materials having low crack levels have been described in U.S. Pat. No. 6,649,287 incorporated by reference above. In some cases, the gallium nitride material region a crack level of less than 0.005 μm/μm². In some cases, the gallium nitride material region has a very low crack level of less than 0.001 μm/μm². In certain cases, it may be preferable for gallium nitride material region to be substantially crack-free as defined by a crack level of less than 0.0001 μm/μm².

In certain cases, the gallium nitride material region includes a layer or layers which have a monocrystalline structure. In some cases, the gallium nitride material region includes one or more layers having a Wurtzite (hexagonal) structure.

The thickness of the gallium nitride material region and the number of different layers are dictated, at least in part, by the requirements of the specific device. At a minimum, the thickness of the gallium nitride material region is sufficient to permit formation of the desired structure or device. The gallium nitride material region generally has a thickness of greater than 0.1 micron, though not always. In other cases, gallium nitride material region 12 has a thickness of greater than 0.5 micron, greater than 0.75 micron, greater than 1.0 microns, greater than 2.0 microns, or even greater than 5.0 microns.

The source, drain and gate electrodes may be formed of any suitable conductive material such as metals (e.g., Au, Ni, Pt), metal compounds (e.g., WSi, WSiN), alloys, semiconductors, polysilicon, nitrides, or combinations of these materials. In particular, the dimensions of the gate electrode can be important to device performance. In the illustrative embodiment, via 26 formed in the passivating layer defines (at least in part) the gate electrode dimensions. Thus, by controlling the shape of the via, it is possible to define desired gate dimensions. Suitable via and gate dimensions have been described in U.S. patent application Ser. No. 10/740,376, incorporated by reference above.

In some embodiments, electrodes may extend into the gallium nitride material region. For example, electrode material (e.g., metal) deposited on the surface of the gallium nitride material region may diffuse into the gallium nitride material region during a subsequent annealing step (e.g., RTA) when forming the electrode. In particular, the source and drain electrodes may include such a portion diffused into the gallium nitride material region. As used herein, such electrodes are still considered to be formed on the gallium nitride material region.

In the illustrative embodiment, interconnects 35 are provided as conductive pathways that are connected to electrodes of the device. Though the illustrated interconnects are connected to the source and drain electrodes, it should also be understood that other conductive interconnects (not shown) may be connected to the gate electrode. It should be understood that bond wires (not shown) are generally provided to electrically connect the interconnects to a voltage source, thus, providing a conductive pathway from the voltage source to the electrodes on the device.

The device shown in FIGS. 1A and 1B also includes an encapsulation layer 36 which, as known to those of skill in the art, encapsulates underlying layers of the structure to provide chemical and/or electrical protection. The encapsulation layer may be formed of any suitable material including oxides or nitrides.

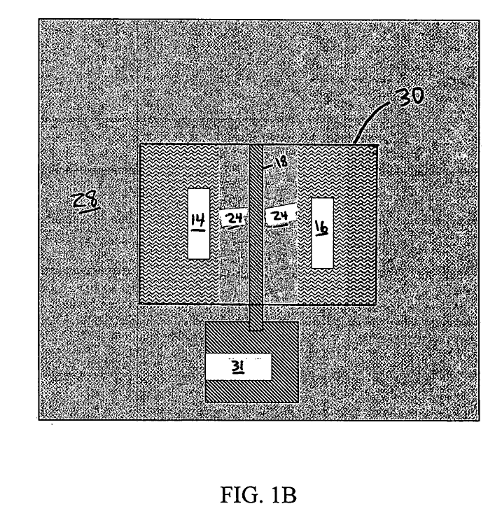

FIG. 2 shows a device 40 according to another embodiment of the invention. Device 40 is a FET similar to device 10 illustrated in FIG. 1, though device 40 includes additional layers that are not shown in FIG. 1. Device 40 includes a strain-absorbing layer 42 formed directly on the surface of substrate 20. Suitable strain-absorbing layers have been described in commonly-owned, co-pending U.S. patent application Ser. No., not yet assigned, entitled “Gallium Nitride Materials and Methods Associated With the Same”, filed Jun. 28, 2004, which is incorporated herein by reference. In one embodiment, it may be preferable for the strain-absorbing layer to be very thin (e.g., thickness of between about 10 Angstroms and about 100 Angstroms) and formed of an amorphous silicon nitride-based material.

In the illustrative embodiment, device 40 includes an overlying layer 44 formed between the strain-absorbing layer and transition layer 22. Suitable overlying layers (and transition layers) have been described in U.S. patent application Ser. No., not yet assigned, entitled “Gallium Nitride Materials and Methods Associated With the Same”, filed Jun. 28, 2004, which is incorporated herein by reference above. An overlying layer, when present, having a reduced misfit dislocation density may be preferred. The overlying layer may be formed of a nitride-based material such as aluminum nitride or an aluminum nitride alloy. In one preferred embodiment, the device includes an amorphous silicon nitride-based material strain-absorbing layer, an aluminum nitride overlying layer and a compositionally-graded transition layer.

It should also be understood that, in some embodiments, the transition layer is formed directly on the stress-absorbing layer and that no separate overlying layer is present.

Other embodiments of the invention may include different layer arrangements than those specifically shown herein. In some embodiments, other layers (e.g., intermediate layers) may be present. Suitable intermediate layers, for example, have been described and illustrated in U.S. Pat. No. 6,649,287, which was incorporated by reference above. In other embodiments of the invention, layer(s) shown herein may not be present. Other variations to the structures and devices shown herein would be known to those of skill in the art and are encompassed by the present invention.

As noted above, devices (e.g., FETs) of the invention may advantageously have low leakage currents. For example, in some embodiments, the devices (e.g., FETs) of the invention have leakage current of less than 0.1 mA/mm gate width at an operating voltage of between about 10 V and about 120 V; or, a leakage current of less than 1 mA/mm gate width at an operating voltage of between about 100 V and about 1 kV. The above-described leakage currents are achievable, and particularly low, in gallium nitride material-based FETs that include a silicon substrate.

It should be understood that, in some embodiments of the invention, devices have leakage currents, outside the above-described ranges.

As used herein, leakage current is defined as any current flow into or out of an electrode of the device when the device is biased in the “off-state.” Leakage current can exist inside the active region, outside the active region, or both, as would be understood by those of ordinary skill in the art. The leakage current of a FET device includes contributions of gate leakage and source leakage, which combine to equal the overall drain leakage. Leakage currents can be measured by conventional techniques including current-voltage (I-V) measurements.

Isolation region 28 effectively reduces the leakage current, particularly in devices that include a passivating layer 24 (e.g., formed of silicon nitride-based materials). As discussed further below in the Examples, the presence of a passivating layer can significantly increase leakage current in devices that include an active region in the gallium nitride material region. It has been discovered that forming isolation regions can effectively reduce the leakage current to acceptable levels in such devices (e.g., FETs) that include a passivating layer and a gallium nitride material region. Using isolation regions to isolate and reduce leakage current may be more effective in reducing leakage current than using conventional mesa etching isolation techniques (particularly when a passivating layer is present), as discussed further below in the Examples. Thus, embodiments of the invention may be free of mesa-etched structures.

In particular, it is believed that the isolation region is effective in reducing the source leakage current. Without being bound by any theory, it is believed that the isolation region reduces source leakage current by limiting (or preventing) leakage current flow from the source outside of the active region to, for example, conducting structures. Such conducting structures include gate and drain electrodes; contact pads of the source, drain and gate electrodes; and, active regions of adjacent device(s) formed on the same substrate. The isolation region is particularly effective in reducing leakage current flow (e.g., outside of the active region) from the source electrode to the drain electrode.

One embodiment of the invention, is a method for reducing increases in leakage current in a device that would otherwise result from the deposition of a passivating layer by forming an isolation region in a gallium nitride material region. For example, in one embodiment, the methods comprise forming an isolation region in a gallium nitride material region of a FET; and forming a passivating layer on a gallium nitride material region of the FET without increasing leakage current of the FET by greater than about 100% at a drain bias of 28 V. In another embodiment, the method involves forming a passivating layer on a gallium nitride material region of the FET without increasing leakage current of the FET by greater than about 50% at a drain bias of 28 V. In another embodiment, the method involves forming a passivating layer on a gallium nitride material region of the FET without increasing leakage current of the FET by greater than about 10% at a drain bias of 28 V.

One embodiment of the invention is a method for reducing increases in isolation current that would otherwise result from the deposition of a passivating layer by forming an isolation region in a gallium nitride material region. As used herein, isolation current is defined as current flow between two electrically isolated structures. Isolation currents can be measured by conventional techniques including current-voltage (I-V) measurements. For example, in one embodiment, the methods comprise forming an isolation region in a gallium nitride material region of a device; and forming a passivating layer on a gallium nitride material region of a device without increasing the isolation current of the isolation region by a factor of greater than about 100 times. In other embodiments, the method involves forming a passivating layer on a gallium nitride material region of a device without increasing the isolation current of the isolation region by a factor of greater than about 10 times. In other embodiments, forming a passivating layer on a gallium nitride material region of a device without increasing the isolation current of the isolation region by a factor of greater than about 2 times.

Devices (e.g., FETs) of the invention may also advantageously have high breakdown voltages. The breakdown voltage for a FET is the operating voltage of the FET device at which the leakage current is 1 mA/mm gate width. In some embodiments, the breakdown voltage of FETs of the invention are greater than or equal to 40 V per micron of gate-to-drain separation; and, in some embodiments, the breakdown voltage of the FET is greater than or equal to 60 V per micron of gate-to-drain separation.

The high power densities, for example, may be observed at frequencies between about 0.1 GHz and about 20 GHz. At an operating voltage of about 10 V, devices (e.g., FETs) may have a power density of between about 1 W/mm and abut 5 W/mm. At an operating voltage of about 28 V, devices (e.g., FETs) may have a power density of between about 1 W/mm and about 10 W/mm. For example, the FETs are capable of operating at a power density of at least 5 W/mm, at least about 7 W/mm, or at least about 8 W/mm, when biased at 28 Volts. At an operating voltage of about 50 V, devices (e.g., FETs) may have a power density of between about 1 W/mm and about 50 W/mm. For example, at an operating voltage of 50 Volts, the FETs are capable of operating at a power density of at least 5 W/mm, at least about 7 W/mm, or at least about 8 W/mm, when biased at 50 Volts. High power densities (e.g., greater than about 50 W/mm) are obtainable at higher operating voltages (e.g., greater than about 50 V).

The above-described power densities are achievable, and particularly high, in gallium nitride material-based FETs that include a silicon substrate. The high power densities result, in part, from the low leakage currents. Power density is an important requirement in many device applications including RF devices (e.g., FETs).

It should be understood the power density of a particular device depends on a number of other parameters and/or operating conditions (e.g., maximum drain current, current gain, device layout, active region geometry, and quiescent bias conditions) and, to some extent, may be tailored. In some embodiments, devices have power densities outside the above-described ranges.

Devices (e.g., FETs) of the invention may also have high operating voltages. For example, in some embodiments, devices have an operating voltage of greater than about 20 V; in some embodiments, greater than about 100 V; and, in other embodiments greater than about 300 V. The above-mentioned operating voltages are achievable, and particularly high, in gallium nitride material-based FETs that include a silicon substrate. The high operating voltages result, in part, from the low leakage currents. Operating voltage is an important requirement in many device applications including RF devices (e.g., FETs) and solid-state switches.

It should be understood the operating voltage of a particular device depends on a number of parameters and/or operating conditions (e.g., maximum drain current, current gain, device layout, active region geometry, and quiescent bias conditions) and, to some extent, may be tailored. In some embodiments, devices have operating voltages outside the above-described ranges.

Devices and structures of the present invention may be formed using methods that employ conventional processing techniques. For example, the layers and regions of the structure may be deposited, patterned, etched and implanted using conventional techniques.

Transition layer 22 and gallium nitride material region 12 may be deposited, for example, using metal organic chemical vapor deposition (MOCVD), molecular beam epitaxy (MBE), and hydride vapor phase epitaxy (HVPE), amongst other techniques. The preferred technique may depend, in part, on the composition of the layers. An MOCVD process may be preferred. A suitable MOCVD process to form a transition layer (e.g., a compositionally-graded transition layer) and gallium nitride material region over a silicon substrate has been described in U.S. Pat. No. 6,649,287 incorporated by reference above. When the semiconductor material region has different layers, in some cases it is preferable to use a single deposition step (e.g., an MOCVD step) to form the entire gallium nitride material region. When using the single deposition step, the processing parameters are suitably changed at the appropriate time to form the different layers. In certain preferred cases, a single growth step may be used to form the transition layer and the gallium nitride material region.

In other embodiments of the invention (not shown), it is possible to grow a semiconductor material (e.g., gallium nitride material) region using a lateral epitaxial overgrowth (LEO) technique that involves growing an underlying semiconductor material layer through mask openings and then laterally over the mask to form the region, for example, as described in U.S. Pat. No. 6,051,849.

In other embodiments of the invention (not shown), it is possible to grow the semiconductor material (e.g., gallium nitride material) region using a pendeoepitaxial technique that involves growing sidewalls of posts into trenches until growth from adjacent sidewalls coalesces to form a semiconductor material region, for example, as described in U.S. Pat. No. 6,265,289. In these lateral growth techniques, semiconductor material (e.g., gallium nitride material) regions with very low defect densities are achievable. For example, at least a portion of the semiconductor material (e.g., gallium nitride material) region may have a defect density of less than about 10⁵ defects/cm².

When present, stress-absorbing layer 42 may be formed using techniques described in U.S. patent application Ser. No., not yet assigned, entitled “Gallium Nitride Materials and Methods Associated With the Same”, filed Jun. 28, 2004 which is incorporated by reference above. For example, the stress-absorbing layer may be formed by nitridating a top surface of a silicon substrate. That is, allowing nitrogen to react with the top surface of the silicon substrate to form a silicon nitride-based layer. The top surface may be nitridated by exposing the silicon substrate to a gaseous source of nitrogen at elevated temperatures.

When present, overlying layer 44 may be formed using techniques described in U.S. patent application Ser. No., not yet assigned, entitled “Gallium Nitride Materials and Methods Associated With the Same”, filed Jun. 28, 2004 which is incorporated by reference above. In some embodiments, the stress-absorbing layer may be formed in-situ with the overlying layer (and, in some cases, subsequent layers) of the structure. That is, the stress-absorbing layer may be formed during the same deposition step as the overlying layer (and, in some cases, subsequent layers). In processes that grow a silicon nitride-based material stress-absorbing layer by introducing a nitrogen source into a reaction chamber, a second source gas may be introduced into the chamber after a selected time delay after the nitrogen source.

Passivating layer 24 may be deposited using any suitable technique. The technique used, in part, depends on the composition of the passivating layer. Suitable techniques include, but are not limited to CVD, PECVD, LP-CVD, ECR-CVD, ICP-CVD, evaporation and sputtering. When the passivating layer is formed of a silicon nitride material, it may be preferable to use PECVD to deposit the layer.

When present, via 26 may be formed within the passivating layer using an etching technique. A plasma etching technique is preferably used to form the via with controlled dimensions

Source, drain and gate electrodes may be deposited on the gallium nitride material region using known techniques such as an evaporation technique. In cases when the electrodes include two metals, then the metals are typically deposited in successive steps. The deposited metal layer may be patterned using conventional methods to form the electrodes. In some embodiments, an annealing step (e.g., RTA) may also be used in which the deposited electrode material diffuses into the gallium nitride material region, particularly when forming source and drain electrodes.

Suitable techniques for forming the passivating layer, via and electrodes have been described in commonly owned, co-pending U.S. patent application Ser. No. 10/740,376, which is incorporated herein by reference above.

As noted above, the isolation region may be formed using an implantation step. In general, any implantation conditions that produce a region having the desired dimensions (e.g., depth) and resistivity can be used. Suitable implant species include, but are not limited to, nitrogen ions, argon ions, helium ions, oxygen ions, and types of radiation (e.g., neutrons), amongst others. Suitable implant doses (particularly when implanting nitrogen ions) may be, for example, between about 10¹² atoms/cm² and about 10¹⁴ atoms/cm². In some processes, multiple implant energies may be used to form a vacancy concentration profile that is relatively constant. For example, implant energies of 30 keV, 160 keV and 400 keV may be used in successive implant steps to form an isolation region having a relatively constant vacancy concentration profile.

It should also be understood that the isolation region may be formed in processes other than implantation. In general, other suitable processes may be used that impart sufficient resistivity to the isolation region to provide the desired isolation. For example, one suitable process may involve exposing the gallium nitride material region to sufficient electromagnetic energy (e.g., a laser).

In some methods, the isolation region is formed after the passivating layer. In some methods, the isolation region is also formed after the gate, source and drain electrodes. However, it should be understood that the isolation region may be formed prior to the passivating layer and/or prior to the gate, source and drain electrodes.

It should be understood that the invention encompasses other methods than those specifically described herein. Also, variations to the methods described above would be known to those of ordinary skill in the art and are within the scope of the invention.

The following examples are not limiting and are presented for purposes of illustration.

### EXAMPLE 1

This example describes production and characterization of HFET devices that include a gallium nitride material device region. An isolation region is formed in the gallium nitride material region.

All structural layers in this example were grown by MOCVD using conventional precursors in a cold-wall, rotating disc reactor designed from flow dynamic simulations. The process used high-resistivity 100 mm Si (111) wafers as substrates. An aluminum nitride layer having a thickness of about 400 nm was grown on the surface of the substrate. It is believed that a very thin (e.g., about 20 Angstroms) amorphous silicon nitride layer may be formed between the aluminum nitride layer and the silicon substrate.. A compositionally graded AlₓGa₍₁₋ₓ₎N transition layer was grown on the aluminum nitride layer with the value of x decreasing across from a back surface of the transition layer to a front surface of the transition layer. A UID gallium nitride (i.e., GaN) buffer layer was grown on the transition layer having a thickness of about 800 nanometers. The structures included 16-20 nanometers total thickness of an Al_{0.26}Ga_{0.74}N barrier layer and capping layer. The growth temperature for all of the above-mentioned layers was 1030° C.

The process included a Ti/Al/Ni/Au ohmic metallization step followed by a rapid thermal annealing (i.e., RTA) step in flowing N₂ at about 825° C. to form source and drain electrodes. Contact resistance, specific contact resistivity, and specific on-resistance of a representative resulting structure were 0.45 Ωmm, 5×10⁻⁶ Ωcm², and 2.2 Ωmm, respectively.

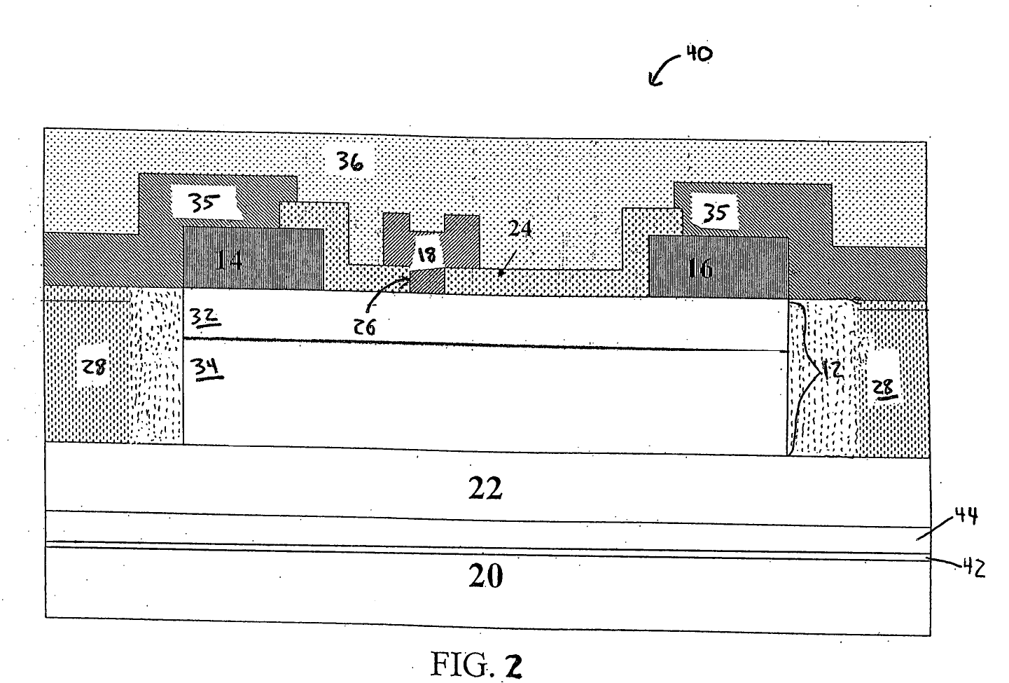

Immediately following the RTA anneal, a SiNₓ passivating layer was deposited having a thickness of about 900 Angstroms in a PECVD step. A sheet resistance (Rₛₕ) uniformity map obtained from van der Pauw cross bridge measurements of one representative structure following the passivation step is shown in FIG. 3. The structure had a mean Rₛₕ of 300 n/square. This corresponds to an excellent 2DEG sheet charge×mobility product of 2.1×10¹⁶ (Vs)⁻¹. The standard deviation of Rₛₕ across the 100 mm diameter (with 5 mm edge exclusion) was 10 Ω/square with full-scale range (R_{sh,max}−R_{sh,min}) of 38 Ω/square.

An isolation region that extended through the thickness of GaN buffer layer was formed in an ion implantation step. This step involved implanting nitrogen ions at multiple implant energies of 30 keV (dose=6×10¹²/cm²), 160 keV (dose=1.8×10¹³/cm²) and 400 keV (dose=2.5×10¹³/cm²). A Monte-Carlo simulation under these conditions shows a vacancy concentration of greater than 10²⁰ vacancies/cm³ to a depth of about 0.6 micron from the surface.

A gate electrode (2×50 micron×0.7 micron) was formed by selectively removing the SiNₓ passivating layer in a fluorine-based dry etch chemistry and subsequent deposition of Ni/Au metal. Source, gate and drain contact pads were deposited simultaneously with the gate electrode metallization. Large periphery devices were air-bridged for source interconnection to a thickness of about 3 micron using standard Au electroplating techniques.

The resulting HFET structure included an isolation region that completely surrounded the active region formed in the Al_{0.26}Ga_{0.74}N and GaN layers.

The HFET structures were characterized using several standard techniques.

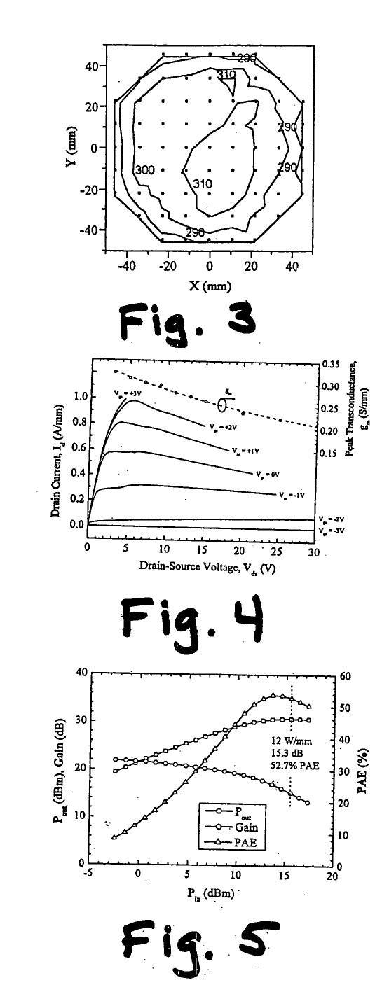

FIG. 4 shows typical output characteristics of the HFET structures with a drain current density of about 1 A/mm and excellent pinch-off characteristics. Process control monitor (PCM) single-finger 100 micron gate width transistors were probed on each of the 69 reticles of the 100 mm wafer and yielded a mean maximum drain current density of 1040±40 mA/mm (defined at a forward gate current density of 1 mA/mm) with no excluded die.

FIG. 4 also shows the drain bias (V_{ds}) dependence of the maximum extrinsic transconductance (gₘ) for V_{ds} up to 30 V. The peak extrinsic gₘ reached 325 mS/mm at low V_{ds} and remained greater than 200 mS/mm beyond V_{ds} of 30V. From the measured source resistance of 0.86 Ωmm, a maximum intrinsic gₘ of 450 mS/mm was estimated. The gate-source bias corresponding to the transconductance peak shifted from −1.4 V at V_{ds}=5 V to −1 V at V_{ds}=30 V.

Three-terminal destructive breakdown voltage for small periphery devices was 60-70 Volts per micron of gate-drain spacing, yielding about 200 Volts for the geometry used in this study. Die yield for breakdown voltage was about 90%, with all excluded (i.e., failed) die originating from the wafer perimeter, likely due to processing irregularities.

Average drain leakage current density measured on PCM 2×200 micron gate width devices was about 0.3 mA/mm at V_{ds}=150 V and V_{gs}=−8 V. This is a very low leakage current for the drain current density (and other parameters/properties) described herein which is, in part, due to the presence of the implanted region.

The leakage/breakdown behavior was dominated by the gate-drain diode at all voltages. In such FET devices, the breakdown voltage may be scaled by varying the spacing between the gate and drain electrodes (e.g., doubling the gate-drain spacing approximately doubles the breakdown voltage).

Scattering parameters were measured with an Agilent 8510C Vector Network Analyzer calibrated to 30 GHz. Wafers were thinned to about 150 micron and backmetallized with 0.5 micron Au prior to small- and large-signal RF data collection. At V_{ds}=15 V and quiescent current (I_{dq}) of 25% I_{D,max}, measured values of cutoff frequency (f_{T}) and maximum frequency of oscillation (fₘₐₓ) were 18 GHz and 31 GHz, respectively. The f_{T}×gate length product of 12.6 GHz·micron is very high for gallium nitride material-based FETs including silicon substrates.

All large-signal measurements were performed on-wafer at 2.14 GHz under CW conditions using Focus Microwaves tuners. Data were collected at 25° C. from 2×50 micron×0.7 micron HFETs on thinned, backmetallized wafers. No through-wafer vias were present. Devices were biased at V_{ds}=50 V and V_{gs}=−1.1 V and were matched for gain and power on the input and output, respectively. Tuning was performed at an input power level of 13 dBm. At the optimized tuner states, the source and load reflection coefficients at the DUT were Γ_{source}=0.77e^{j18°} and Γ_{load}=0.85e^{j1°}. The system integrity was verified to a net loss of 0.3 dB on a 50 Ω through.

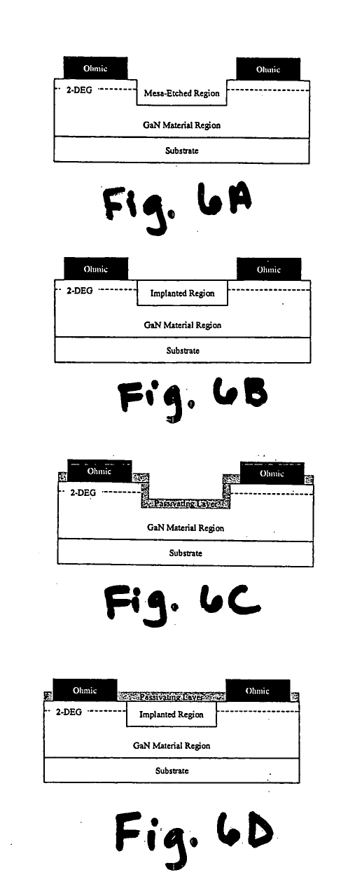

A 50 V power sweep is shown in FIG. 5, illustrating 30.8 dBm saturated output power with associated large-signal gain of 15.3 dB and power-added efficiency (PAE) of 52.7%. This corresponds to a power density of 12 W/mm which represents a very high power density for a GaN-based device grown on a silicon substrate. Peak PAE and drain efficiency reached 53.7% and 54.8%, respectively. However, the maximum impedance of about 600 Ω available from the output tuner resulted in a current-limited load line for these small periphery devices. Drain efficiency values of about 70% were obtained in class AB operation on larger devices and at lower V_{ds}, where proper matching was obtainable with a reduced load impedance.

This example illustrates production of HFET devices including a silicon substrate, gallium nitride material device region and an isolation region, amongst other features. The devices have excellent electrical properties including low leakage currents.

### EXAMPLE 2

This example compares interdevice isolation current of gallium nitride material-based structures that include isolation regions of the invention to gallium nitride material-based structures that are mesa-etched for isolation. The isolation current is the current between two structures (e.g., ohmic electrodes) separated by an isolation region. Also, the effect of a SiNₓ passivating layer on isolation current in these structures is investigated.

Gallium nitride material-based structures were produced similar to those described in Example 1 through the ohmic metallization and rapid thermal annealing steps.

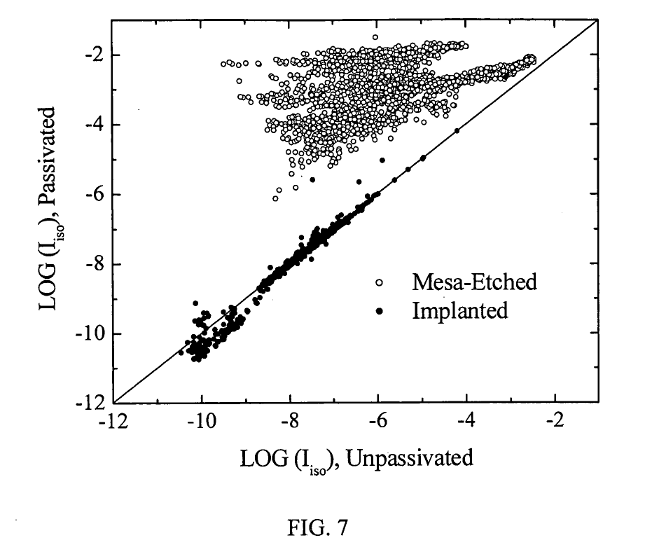

A first set of structures was processed using a mesa etching isolation process. Mesa-etched structures were produced by ICP dry etching in a BCl₃/Cl₂/Ar chemistry with a gas ratio of 8:32:10. The RF and ICP powers were 40W and 100W, respectively, and the chamber was maintained at 5 mTorr during the etch process. This recipe has been controlled to produce a smooth sidewall profile with minimal etch damage to the underlying GaN. The etch rate was approximately 9 Angstroms/sec. under these conditions. The etch depth was approximately 1000 Angstroms, sufficient to remove the AlGaN barrier, 2DEG region, and a portion of the GaN buffer layer. FIG. 6A shows a cross-section of the structures.

A second set of structures was processed using an ion implantation step similar to the one described in Example 1. FIG. 6B shows a cross-section of the structures.

Isolation current between the two ohmic electrodes was measured at an applied voltage of 40 V using standard current-voltage techniques. The length of the isolated material region (either mesa-etched or implanted) was 5 microns and the width of the test structure was 100 microns.

After measurement of the isolation current of the test structures, both sets of structures were passivated with a SiNₓ passivating layer. FIG. 6C shows a cross-section of the mesa-etched test structures including the passivating layer and FIG. 6D shows a cross-section of the test structures including an implanted isolation region and the passivating layer. The isolation current was measured for both sets of passivated test structures following the same procedure as described above.

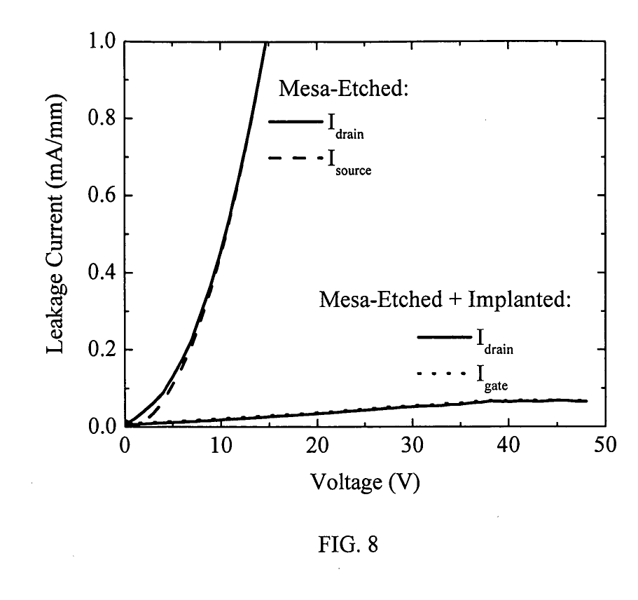

FIG. 7 is a log-log plot of passivated isolation current vs. unpassivated isolation current for both mesa-etched and implanted isolation structures. The structures including implanted isolation regions exhibit no change in isolation current after passivation, as evidenced by the linear relationship with a slope of about one. In sharp contrast, the mesa-etched structures exhibit a significant increase in isolation current after passivation. This increase can be up to 5-6 orders of magnitude, depending on the level of unpassivated isolation current.

In general, structures including the implanted isolation region had lower isolation currents than mesa-etched structures for both the passivated and unpassivated structures with the difference being greater for passivated structures.

The fact that the passivated isolation current is largely independent of the magnitude of unpassivated isolation current for the mesa-etched structures suggests that a leakage path may exist at the interface of the SiNₓ passivating layer and the underlying GaN material region. As evidenced by FIG. 7, this path does not exist for the implanted isolation structures, enabling the passivated isolation current to be determined by the magnitude of unpassivated isolation current. The latter can be controlled to some extent by the conditions of the material growth and/or the ion implantation step.

This example illustrates production of GaN material structures including an implanted material region having excellent electrical isolation characteristics. Low isolation currents are advantageous in electronic and optoelectronic devices to reduce leakage current. [Let's discuss tie in.]

### EXAMPLE 3

This example compares properties of gallium nitride material-based HFET devices including mesa-etched structures before, and after, an implantation step that forms an isolation region.

Gallium nitride material-based HFET structures (2×0.7 micron×50 micron) including mesa-etched isolation regions were produced, using techniques similar to those described in Example 2. HFET device fabrication then proceeded through ohmic metallization and rapid thermal annealing, gate metallization, contact pad metallization, then SiNx passivation. After passivation, leakage current of the HFET structures was characterized by current-voltage techniques. The source electrode was grounded and the gate was biased in “hard pinch-off” at −8 V. The drain voltage (V_{ds}) was swept from 0 V to positive voltage and source, gate, and drain leakage currents were monitored as a function of V_{ds}.

After current-voltage data were collected, the active region of the device was covered with a photoresist implant mask. All remaining portions of the wafer (including contact pads and regions between contact pads) were subjected to an ion implantation step to form an isolation region. The current-voltage measurements were repeated.

FIG. 8 is a graph of leakage current versus voltage for the structures before (mesa-etched), and after implantation (mesa etched+implanted). The results show the devices had significantly lower overall leakage current (i.e., drain leakage, I_{drain}) after formation of the implanted isolation region.

For a representative mesa-etched structure before implantation, the drain leakage current rises near-exponentially and reaches a leakage current density of 1 mA/mm gate width at V_{ds}=15 V. For these structures, the drain leakage (I_{drain}) consisted almost entirely of source leakage (I_{source}) above V_{ds}=5 V (i.e. the gate leakage contribution to the drain leakage was negligible compared to the source leakage).

After the ion implantation step, the leakage current was reduced more than an order of magnitude at V_{ds}=15 V and remained less than 0.1 mA/mm to beyond V_{ds}=45 V. For a representative mesa-etched and implanted structure, the leakage current consisted almost entirely of gate current (I_{gate}). Thus, the formation of the implanted isolation region substantially reduced the source leakage current (I_{source}) and, consequently, the overall leakage current (I_{drain}). This reduction in leakage current allowed mesa-etched and implanted HFET structures to achieve significantly higher operating voltage than mesa-etched HFET structures. Before implantation, the devices sustained an RF quiescent bias point (I_{dq}) of about 15 V, while, devices after implantation, sustained an RF quiescent bias point (I_{dq}) of about 28 V.

This example illustrates that the high leakage currents of gallium nitride material-based HFETs including mesa-etched structures may be reduced using an implantation step to form an isolation region of the present invention.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

1. A semiconductor device comprising:
a silicon substrate;
a gallium nitride material region formed on the silicon substrate and having an active region formed therein;
a passivating layer formed on the gallium nitride material region; and
an isolation region formed in the gallium nitride material region and electrically isolating, at least in part, the active region.

2. The device of claim 1, wherein the isolation region has a vacancy concentration of greater than about 10¹⁸ vacancies/cm³.

3. The device of claim 1, wherein the isolation region has a sheet resistance of greater than about 10⁹ Ohms/sq.

4. The device of claim 1, wherein the isolation region comprises amorphized material.

5. The device of claim 1, wherein the isolation region is an implanted region.

6. The device of claim 1, wherein the isolation region electrically isolates the active region of the device.

7. The device of claim 1, wherein the isolation region extends completely through the gallium nitride material region.

8. The device of claim 1, wherein the gallium nitride material region comprises a first gallium nitride material layer and a second gallium nitride material layer.

9. The device of claim 1, wherein the passivating layer comprises a nitride-based compound.

10. The device of claim 9, wherein the passivating layer comprises a silicon nitride compound.

11. The device of claim 1, further comprising an electrode defined, at least in part, within a via formed in the passivating layer.

12. The device of claim 1, wherein the device is a FET and further comprises a source electrode, a gate electrode, and a drain electrode.

13. The device of claim 12, wherein the isolation region reduces leakage current flow outside of the active region from the source electrode to at least one conducting structure.

14. The device of claim 12, wherein the isolation region reduces leakage current flow outside of the active region from the source electrode to the drain electrode.

15. The device of claim 1, further comprising a compositionally-graded transition layer formed between the substrate and the gallium nitride material region.

16. The device of claim 15, wherein the compositionally graded transition layer comprises AlₓGa₍₁₋ₓ₎N and x is decreased from a back surface of the transition layer to a front surface of the transition layer

17. The device of claim 1, further comprising a silicon nitride-based material layer covering a majority of the top surface of the substrate.

18. The device of claim 17, wherein the silicon nitride-based material layer has a thickness of less than 100 Angstroms.

19. The device of claim 1, wherein the device is a FET.

20. The device of claim 1, wherein the device is free of mesa-etched structures.

21. A method comprising:
forming an isolation region in a gallium nitride material region of a device; and
forming a passivating layer on a gallium nitride material region of a device without increasing the isolation current of the isolation region by a factor of greater than about 100 times.

22. The method of claim 21, wherein the isolation region isolates, at least in part, an active region of the device.

23. The method of claim 21, wherein the isolation region has a vacancy concentration of greater than about 10¹⁸ vacancies/cm³.

24. The method of claim 21, comprising forming the passivating layer on a gallium nitride material region of a device without increasing the isolation current of the isolation region by a factor of greater than about 10 times.

25. The method of claim 21, comprising forming the passivating layer on a gallium nitride material region of a device without increasing the isolation current of the isolation region by a factor of greater than about 2 times.

26. The method of claim 21, comprising forming the passivating layer on a gallium nitride material region of a device without increasing the isolation current of the isolation region.

27. The method of claim 21, wherein the isolation current is between about 10 picoAmps and about 10 microAmps.

28. The method of claim 21, comprising forming the isolation region in an implantation step.

29. The method of claim 21, wherein the passivating layer comprises a nitride-based compound.

30. The method of claim 21, wherein the passivating layer comprises a silicon nitride-based material.

31. The method of claim 21, wherein the device is a FET comprising a source electrode, a gate electrode, and a drain electrode.

32. A method comprising:
forming an isolation region in a gallium nitride material region of a FET; and
forming a passivating layer on a gallium nitride material region of the FET without increasing leakage current of the FET by greater than about 100% at a drain bias of 28 V.

33. The method of claim 32, comprising forming a passivating layer on a gallium nitride material region of the FET without increasing leakage current of the FET by greater than about 50% at a drain bias of 28 V.

34. The method of claim 34, comprising forming a passivating layer on a gallium nitride material region of the FET without increasing leakage current of the FET by greater than about 10% at a drain bias of 28 V.

35. A FET comprising:
a silicon substrate; and
a gallium nitride material region formed over the silicon substrate, wherein the FET is capable of operating at a power density of at least 7 W/mm when biased at 28 Volts.

36. The FET of claim 35, wherein the FET is capable of operating at a power density of at least 8 W/mm when biased at 28 Volts.

37. The FET of claim 35, wherein the FET is capable of operating at a power density of at least 10 W/mm when biased at 50 Volts.

38. A FET comprising:
a silicon substrate;
a gallium nitride material region formed over the silicon substrate;
an implanted region formed in the gallium nitride material region; and
wherein the FET is capable of operating at a power density of at least 5 W/mm when biased at greater than or equal to 28 Volts.

39. The FET of claim 38, wherein the FET is capable of operating at a power density of at least 5 W/mm when biased at 28 Volts.

40. A FET comprising:
a silicon substrate; and
a gallium nitride material region formed on the silicon substrate, wherein the breakdown voltage of the FET is greater than or equal to 40 V per micron of gate-to-drain separation.

41. The FET of claim 40, wherein the breakdown voltage of the FET is greater than or equal to 60 V per micron of gate-to-drain separation.

42. The method of claim
